(19) United States
(12) Patent Application Publication
(10) Pub. No.: US 2026/0362681 A1
(43) Pub. Date: Nov. 12, 2026

(54) APPARATUS INCLUDING BIT LINE SIDE WALL STRUCTURE

(71) Applicant: Micron Technology, Inc., Boise, ID (US)

(72) Inventor: Hiroki Fujioka, Hiroshima (JP)

(73) Assignee: Micron Technology, Inc., Boise, ID (US)

(21) Appl. No.: 19/650,814

(22) Filed: Apr. 17, 2026

Related U.S. Application Data
(60) Provisional application No. 63/802,989, filed on May 9, 2025.

(51) Int. Cl. H10B 12/00

(52) U.S. Cl. CPC H10B 12/485; H10B 12/0335; H10B 12/482

(57) ABSTRACT

Some embodiments of the disclosure provide an apparatus comprising memory cell capacitors, cell contacts, bit lines, and bit line contacts. The apparatus further comprises a side wall structure. The side wall structure may cover side surfaces of the bit line and the bit line contact. The side wall structure may include inner and outer insulating layers and a middle insulating layer therebetween. The outer insulating layer may include a first vertical portion, and a second vertical portion formed integrally with the first vertical portion. While the bit line contact may extend partway into the semiconductor substrate, the second vertical portion also may extend downwardly below a top surface of the semiconductor substrate. This downwardly extended vertical portion, together with the inner and middle insulating layers, may prevent a short circuit between the bit line contact and the memory cell contact.

### CROSS REFERENCE TO RELATED APPLICATIONS

This application claims the benefit under 35 U.S.C. § 119 of the earlier filing date of U.S. Provisional Application Serial No. 63/802,989 filed May 9, 2025. The aforementioned application is incorporated herein by reference, in its entirety, for any purpose.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines arranged in rows and bit lines arranged in columns. Each memory cell may include a capacitor for data storage and a transistor for accessing the capacitor. A memory cell capacitor may be coupled to either source or drain of an associated memory cell transistor formed in active regions of a semiconductor substrate, via conductive contact elements, such as a cell contact and a redistribution layer. A cell contact may be coupled at one end to either the source or drain region and at another end to a redistribution layer. The redistribution layer may then be coupled to the associated memory cell capacitor. A bit line may be coupled to the other source/drain region via another conductive contact element, such as a bit line contact.

### BRIEF DESCRIPTION OF THE DRAWINGS

FIGS. 1A and 1B depict an example configuration of at least part of a memory device in a plan view and a cross-sectional view, respectively, according to some embodiments of the disclosure.

FIGS. 2A-2B - 6A-6B depict example processes of forming at least part of a memory device in a plan view and a cross-sectional view according to some embodiments of the disclosure.

FIGS. 7A-7B - 8A-8B depict example processes of forming at least part of a memory device in a plan view and a cross-sectional view according to some embodiments of the disclosure.

FIG. 9 depicts a schematic configuration of an example semiconductor system according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

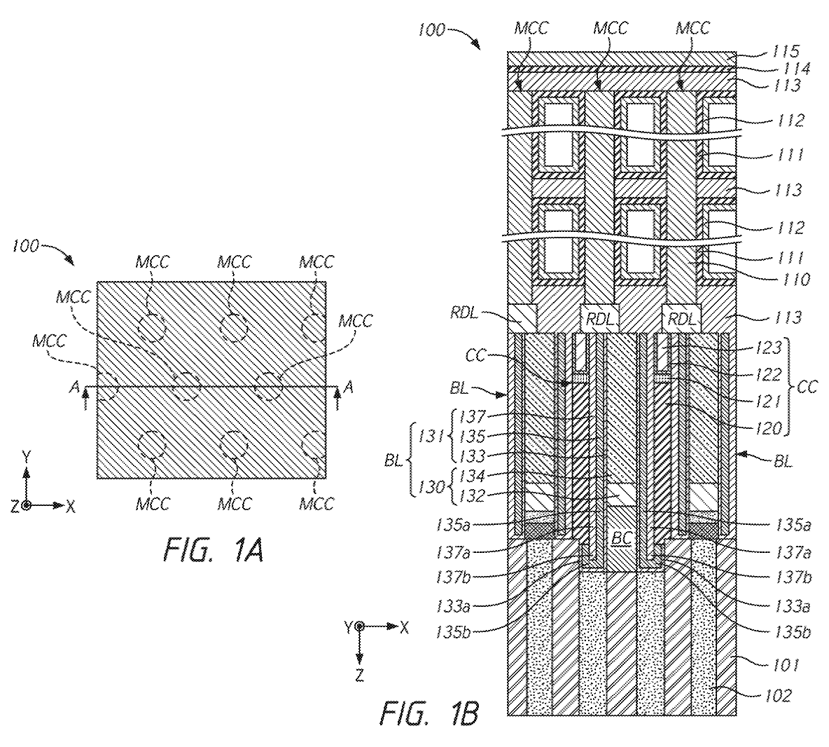

FIGS. 1A and 1B depict an example configuration of at least part of a memory device 100 in a plan view and a cross-sectional view, respectively, according to some embodiments of the disclosure. The cross-sectional view of FIG. 1B corresponds to line A-A in FIG. 1A. The size, position, and other aspects of the cross-sectional view may not necessarily match those of the plan view in the drawings. The memory device 100 may be a dynamic random-access memory (DRAM). The memory device 100 may be one example of a semiconductor device. The memory device 100 may be one example of an apparatus. The depicted example of the memory device 100 shows memory cell capacitors MCC, cell contacts CC, redistribution layers RDL, bit lines BL, and bit line contacts BC. The memory device 100 may include other elements, such as word lines, word line contacts, gate electrodes, or the like, as appropriate. Memory cell capacitors MCC may be coupled to corresponding active regions (one of source and drain regions of a memory cell access transistor, for example) formed in a semiconductor substrate 101 via cell contacts CC and redistribution layers RDL. In some instances, redistribution layers RDL may be part of cell contacts CC. The bit lines BL may be coupled to other corresponding active regions (another of source and drain regions of the access transistor, for example) formed in the semiconductor substrate 101 via bit line contacts BC. In some instances, cell contacts CC and bit line contacts BC may be conductive plugs for memory cell capacitors and bit lines, respectively.

The memory device 100 includes a plurality of memory cell capacitors MCC. The memory cell capacitors MCC each may include a conductive pillar 110. The conductive pillar 110 may serve as a lower (or bottom) capacitor electrode and may include a conductive material, such as a metal (e.g., titanium nitride (TiN)). The conductive pillar 110 may also be referred to as a metal pillar. The memory cell capacitors MCC each may further include a dielectric layer 111 and a conductive layer 112. The conductive layer 112 may serve as an upper (or top) capacitor electrode and may include the same material as the lower electrode, such as TiN. The dielectric layer 111 may be sandwiched between the lower and upper electrodes and may include an insulating material, such as a high dielectric constant/high-k material (e.g., Zirconium Oxide (ZrO₂) and hafnium oxide (HfO₂)). The memory cell capacitors MCC may be pillar-type capacitors. The depicted example configuration may further include insulating layers 113. The insulating layers 113 may include an insulating material, such as a nitride (e.g., silicon nitride (Si₃N₄ or simply SiN)). Another high-k layer 114 and another conductive layer 115 may also be provided on the memory cell capacitors MCC and neighboring structures. In some instances, additional insulating layers and/or conductive layers may be provided as appropriate. The memory cell capacitors MCC may be arranged at intersections of word lines (not separately depicted) and bit lines BL. The memory cell capacitors MCC may be arranged in a matrix. Each memory cell capacitor MCC may form at least part of a memory cell to store data by accumulating electric charges therein and to be accessed via the associated word line and bit line during data write and read operations. Each memory cell capacitor MCC may include a vertical capacitor structure that extends in a vertical direction, which may be for example a Z-axis direction in the drawing. Bit lines BL (may also be referred to as digit lines or data lines) may be arranged in parallel with each other in a first horizontal direction, which may be for example an X-axis direction in the drawing, and each may extend in a second horizontal direction, which may be for example a Y-axis direction in the drawing, perpendicular (or substantially perpendicular within reasonable tolerances of fabrication, measurement, etc.) to the first horizontal direction. Word lines may be arranged in parallel with each other in the Y-axis direction and each may extend in the X-axis direction, intersecting with bit lines BL in the plan view (for example, in a plane along the X-axis direction and the Y-axis direction).

The memory device 100 includes a plurality of cell contacts CC and a plurality of redistribution layers RDL arranged in a matrix corresponding to the matrix of the memory cell capacitors MCC. The cell contacts CC have lower portions coupled to active regions (source/drain regions) formed in the semiconductor substrate 101. The redistribution layers RDL have lower portions and upper portions coupled to the associated cell contacts CC and the associated memory cell capacitors MCC, respectively. The cell contacts CC and the redistributions layer RDL couple the associated memory cell capacitors MCC to the active regions of the semiconductor substrate 101. The redistribution layers RDL are arranged to contact at least upper portions of the cell contacts CC. The redistribution layers RDL may also contact upper portions of the bit lines BL adjacent to the cell contacts CC. The redistribution layers RDL may include a conductive material, such as a metal (e.g., tungsten (W)). Each cell contact CC includes a cell contact structure, which includes a first contact part 120, a second contact part 121, a third contact part 122, and a fourth contact part 123. The first contact part 120 extends vertically (e.g., in the Z-axis direction in the drawing) into the semiconductor substrate 101, and is coupled to the active region formed in the semiconductor substrate 101 at a lower end. The first contact part 120 may include polycrystalline silicon or polysilicon (poly-Si). The first contact part 120 may also be referred to as a contact poly. The second contact part 121 is provided on a top potion of the first contact part 120. The second contact part 121 may include cobalt (Co) or cobalt silicide (CoSi₂). The second contact part 121 may also be referred to as a contact cobalt. The third contact part 122 is provided on the second contact part 121. The third contact part 122 may include a conductive material, such as a metal (e.g., titanium (T) and TiN). The conductive material of the third contact part 122 may serve as a barrier metal. The barrier metal may be provided in a film form including a bottom portion and a side portion. The fourth contact part 123 is provided on the third contact part 122. The fourth contact part 123 may include a conductive material, such as a metal (e.g., W), different from the conductive material of the third contact part 122. The fourth contact part 123 contacts the bottom and side portions of the third contact part 122. The third contact part 122 and the fourth contact part 123 may also be referred to as a barrier metal (or a barrier metal film) and a contact metal, respectively, of the cell contact CC. In some instances, the first and second contact parts 120 and 121 and the third and fourth contact parts 122 and 123 may be formed in a contact hole between neighboring bit lines BL in that order, filling the contact hole. In some instances, other elements, films, layers, or the like may be included in the cell contact structure.

The memory device 100 includes a plurality of bit lines BL. Each bit line BL includes a bit line structure 130, which includes at least a conductive part 132 and an insulating part 134 . The conductive part 132 may include a conductive material, such as a metal (e.g., tungsten (W)). The conductive part 132 may also be referred to as a bit line metal. On the conductive part 132 is the insulating part 134 including an insulating material, such as a nitride (e.g., SiN). The insulating part 134 may serve as a mask layer or a cap layer. Other elements, films, layers, or the like may be included in the bit line structure as appropriate. The bit lines BL may be coupled to active regions (source/drain regions) formed in the semiconductor substrate 101 via bit line contacts BC. Each bit line contact BC may include a conductive material, such as polycrystalline silicon or polysilicon (poly-Si). A lower portion of the bit line contact BC extends partway into the semiconductor substrate 101 and is coupled to the active region. An upper portion of the bit line contact BC is coupled to the conductive part 132 of the associated bit line structure. In the depicted example, the lower portion and the upper portion of the bit line contact BC are positioned below and above a top surface of the semiconductor substrate, respectively. The memory device 100 may also include isolation structures 102, such as shallow trench isolations STI, formed in the semiconductor substrate 101. The isolation structures may include an insulating material, such as an oxide (e.g., silicon dioxide (SiO₂ or simply SiO)).

The bit line BL includes a side wall structure, which is a multi-layered structure. The structure includes an inner insulating layer 133, a middle insulating layer 135, and an outer insulating layer 137. In some instances, the side wall structure may be part of the bit line structure. The inner insulating layer 133 is provided on side surfaces of the bit line BL (including the conductive part 132 and the insulating part 134) and the bit line contact BC. The inner insulating layer 133 may include a first insulating material, such as a nitride (e.g., silicon carbonitride SiCN or SiN). The middle insulating layer 135 The middle insulating layer 135 is provided on the inner insulating layer 133. The middle insulating layer 135 may include a second insulating material, such as an oxide. The second insulating material may be a low dielectric constant/low-k material (e.g., silicon oxycarbide (SiOC), silicon oxycarbonitride (SiOCN)). In other instances, the second insulating material may include silicon dioxide. The middle insulating layer 135 is provided on the inner insulating layer 133. The middle insulating layer 135 is positioned between the inner and outer insulating layers 133 and 137. The middle insulating layer 135 includes a first portion 135a that extends downwardly in the vertical (Z-axis) direction along the inner insulating layer 133. The middle insulating layer 135 further includes, at the end of the first portion 135a, a second portion 135b that bends outwardly in the horizontal (X-axis) direction and upwardly in the vertical (Z-axis) direction, forming a bent lower portion to receive the outer insulating layer 137 at a position next to the lower portion of the bit line contact BC below the top surface of the semiconductor substrate 101. The first portion 135a and the second portion 135b may also be referred to as a vertical portion and a bent portion, respectively. Since the bit line contact BC extends partway into the semiconductor substrate, both the inner insulating layer 133 and the middle insulating layer 135 also extend into the semiconductor substrate 101 along the bit line contact BC. Consequently, the bent portion 135b of the middle insulating layer 135 is positioned below the top surface of the semiconductor substrate 101. In the depicted example, an end portion 133a of the inner insulating layer 133 also bends along the bent portion 135b of the middle insulating layer 135 and covers an outer surface of the bent portion 135b.

The outer insulating layer 137 is provided on the middle insulating layer 135. The outer insulating layer 137 may include a third insulating material, such as a nitride (e.g., SiN). In other instances, the third insulating material may include SiCN. The insulating material of the middle insulating layer 135 may be different from those of the inner and outer insulating layers 133 and 137. The insulating materials of the inner and outer insulating layer 133 and 137 may be the same as or different from each other. In the depicted example, the multi-layer side wall structure includes the inner, middle, and outer insulating layers 133, 135, and 137 as first, second, and third insulating layers in that order from the side surface of at least the bit line BL. The side wall structure may include other layers, films, or elements as appropriate.

The outer insulating layer 137 includes a first portion 137a that extends along the vertical portion 135a of the middle insulating layer 135. The outer insulating layer 137 further includes a second portion 137b that further extends downwardly from the first portion 137a. The second portion 137b is integral with the first portion 137a. The first and second portions 137a and 137b may be formed integrally. The formation of these portions will be described in further detail below. The first portion 137a and the second portion 137b may be an upper vertical portion and a lower vertical portion positioned above and below the top surface of the semiconductor substrate 101, respectively. The first and second portions 137a and 137b may also be referred to as first and second vertical portions, respectively. The second vertical portion 137b is received at the bent portion 135b of the middle insulating layer 135 below the top surface of the semiconductor substrate 101. The second vertical portion 137b is surrounded by the bent portion 135b of the middle insulating layer 135 below the top surface of the semiconductor substrate 101. Compared with the neighboring bit line structure BL illustrated in FIG. 1B with no bit line contact at its lower end, the inner, middle, and outer insulating layers 133, 135, and 137 are further vertically elongated and together cover the side surfaces not only of the bit line BL but also of the bit line contact BC. For example, the second vertical portion 137b of the outer insulating layer 137 is an additional portion extended from the first vertical portion 137a and protruding below the top surface of the semiconductor substrate 101 to cover a lower part of the side surface of the bit line contact BC, the lower part positioned below the top surface of the semiconductor substrate 101. Likewise, lower portions of the inner and middle insulating layers 133 and 135 cover the lower part of the side surface of the bit line contact BC.

Between the neighboring bit lines BL, hence between the neighboring side wall structures, the cell contact CC is provided, including the contact part 120, which is conductive and may include poly-Si. The second vertical portion 137b of the outer insulating layer 137 may protect at least the bit line contact BC from coupling with the cell contact CC. For instance, during the formation of cell contact CC next to the bit line BL and the bit line contact BC, a wet etching process may be used to create a cell contact hole where poly-Si is deposited. In some cases, a wet etchant may penetrate from the cell contact hole and creates a pocket space between the cell contact hole and the neighboring element. When poly-Si is deposited into the cell contact hole, it may leak into the pocket space. The presence of poly-Si in the pocket space may induce a short circuit with the conductive material (such as poly-Si) of the neighboring element, which may be the bit line contact BC. The multi-layer side wall structure according to the present embodiments includes the outer insulting layer 137 with the second vertical portion 137b as described above and can effectively prevent or mitigate penetration of the wet etchant and hence leakage of poly-Si, thereby protecting the neighboring bit line BL and bit line contact BC from a short circuit. Thus, production yields of the memory device can be increased. Furthermore, in the case where a short-circuit protection portion is formed separately from the outer insulating layer 137, the structure of the side wall may become complex. On the other hand, in the case where the outer insulating layer 137 includes the second portion 137b integral with the first portion 137a as in the present embodiments, the side wall structure becomes simpler with a seamless or jointless outer layer, compared to the former case. With the simpler structure, the process also becomes simpler, making device downsizing or miniaturization easier. Hence, the memory device of the present embodiments can achieve further cost reduction and improved scaling of the bit line contact.

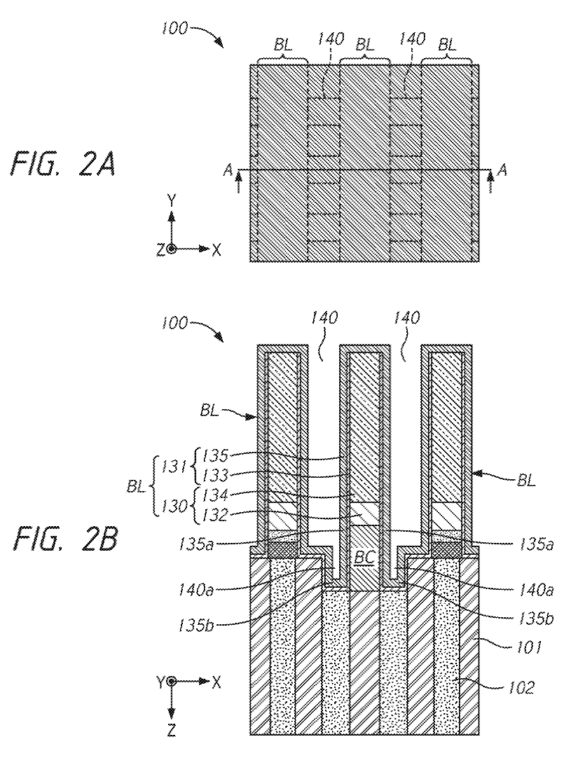

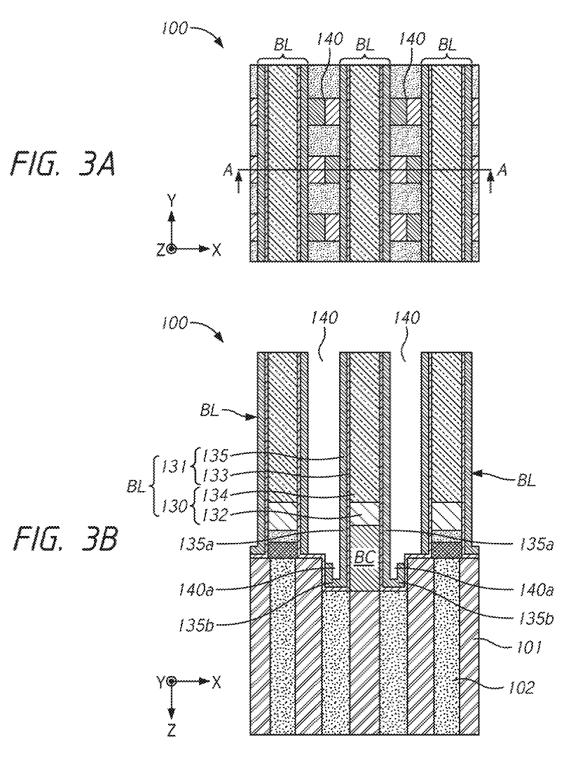

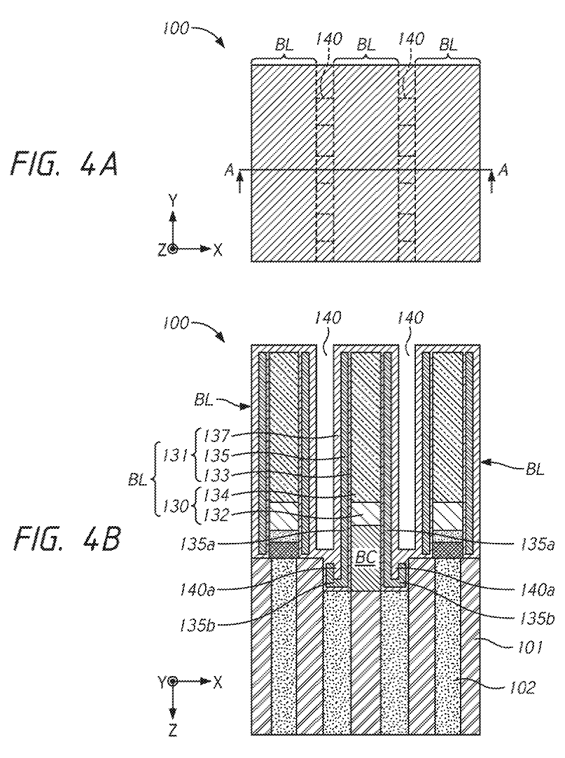

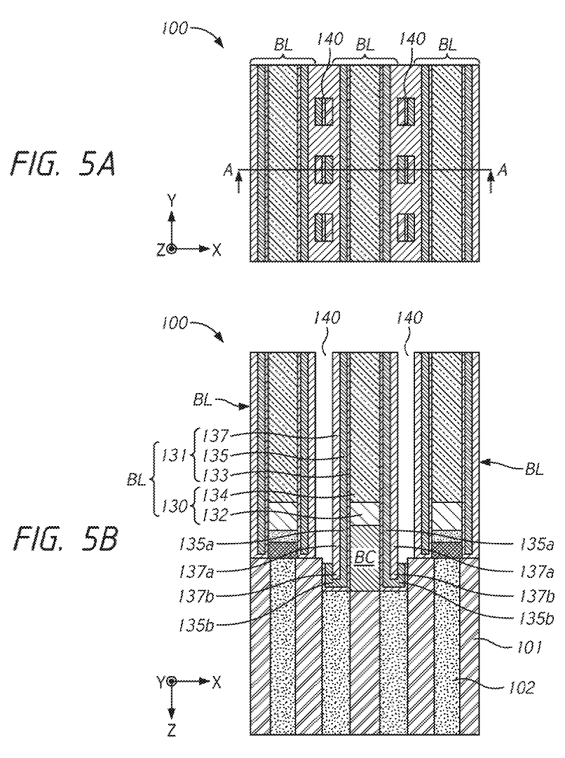

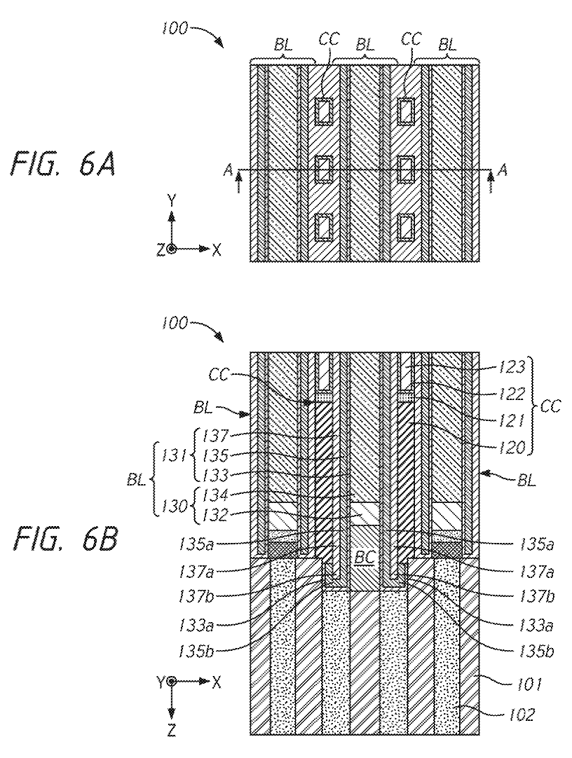

FIGS. 2A-2B - 6A-6B depict example processes of forming at least part of the memory device 100 in a plan view and a cross-sectional view according to some embodiments of the disclosure. FIGS. 2A-6A depict the processes in the plan view. The cross-sectional views in FIGS. 2B-6B correspond to line A-A in FIGS. 2A-6A. The size, position, and other aspects of the cross-sectional view may not necessarily match those of the plan view in the drawings. The memory device 100 of these figures corresponds to the memory device 100 of FIGS. 1A-1B. An example method to form at least part of a memory device according to some embodiments of the disclosure may include the processes described below.

First, as shown in FIGS. 2A and 2B, a part of the memory device 100 is formed, including, for example, the bit lines BL and the bit line contacts BC on the semiconductor substrate 101. Each bit line BL is formed to have at least the conductive part 132 (including W for example) and the insulating part 134 (including SiN for example) stacked on top of each other as part of the bit line structure 130, extending in the vertical (Z-axis) direction. The bit line contact BC (including poly-Si for example) is formed under the conductive part 132 for coupling to the active region in the semiconductor substrate 101. A lower portion of the bit line contact BC extends partway into the semiconductor substrate 101. Known techniques, such as deposition, photolithography, etching, and polishing, may be used to form the bit line structure 130 and the bit line contact BC. Later developed techniques may also be applicable as appropriate. Furthermore, the inner insulating layer 133 (including SiCN for example) and the middle insulating layer 135 (including SiOC or SiOCN for example) are formed on the side surfaces of the bit line BL and the bit line contact BC. Since the bit line contact BC extends partway into the semiconductor substrate, the inner and middle insulating layers 133 and 135 also downwardly extends along the bit line contact BC to cover the side surface thereof below the top surface of the semiconductor substrate 101. For example, an opening 140 is formed by etching between the neighboring bit line structures 130, and a part 140a of the opening 140 extends partway into the semiconductor substrate 101 (more specifically, partway into the insulating structure 102 in the semiconductor substrate 101 in the depicted example) along the side surface of the lower portion of the bit line contact BC. The insulating materials of the inner and middle insulating layers 133 and 135 are then deposited in the opening 140 to cover the side and bottom surfaces thereof. The middle insulating layer 135 hence formed on the inner insulating layer 133 in the opening 140 has the vertical portion 135a extending downwardly and the bent portion 135b extending outwardly and upwardly in the part 140a of the opening 140, both portions formed integrally.

Next, as shown in FIGS. 3A and 3B, part of the middle insulating layer 135 is removed, for example by etching, from the bottom of the opening 140 including the extended opening part 140a. This shapes the bent portion 135b of the middle insulating layer 135 so that it has the intended upward portion. Etching conditions, including but not limited to etchant, etching time, pressure, gas flow rate, temperature, may be appropriately adjusted so that the intended part of the middle insulating layer 135 is removed while the other part remains on the inner insulating layer 133 in the opening 140.

As shown in FIGS. 4A -4B and 5A-5B, the insulating material (such as SiN) of the outer insulating layer 137 is then deposited on the exposed surfaces of the inner and middle insulating layers 133 and 135 in the opening 140, and the outer insulating layer 137 is shaped to have the intended second portion 137b formed integrally at the end of the first portion 137a within the part 140a of the opening 140. The second portion 137b is continuous with the first portion 137a, without seams or joints between the two portions. The second portion 137b may be regarded as a downward extension of the first portion 137a and is received at the bent portion 135b of the middle insulating layer 135, below the top surface of the semiconductor substrate 101. For example, a portion of the deposited insulating material is removed from the bottom part of the opening 140 by etching so that at least a top part of the active region in the semiconductor substrate 101 and a top part of the bent portion 135b of the middle insulating layer 135 are exposed. Part of the first portion 137a and/or the second portion 137b of the outer insulating layer 137 is also exposed above the exposed top part of the bent portion 135b of the middle insulating layer 135. The etching process may involve wet etching. During the wet etching, a wet etchant may be used: however, because of the integral formation of first and second portions 137a and 137b of the outer insulating layer 137, the wet etchant does not penetrate into an unintended area, such as an area closer to the neighboring bit line contact BC. This results in the formation of a cell contact hole with the intended shape between the neighboring bit lines BL, without any pocket hole caused by wet etchant penetration. Wet etching conditions, including but not limited to etchant, etching time, pressure, gas flow rate, and temperature, may be appropriately adjusted to ensure that the intended portion of the insulating material is removed while the remaining portion stays within the opening 140, thereby forming the intended cell contact hole.

Subsequently, as shown in FIGS. 6A and 6B, the conductive material (such as poly-Si) of the first contact part 120 of the cell contact CC is deposited in the opening/cell contact hole 140. The first contact part 120 contacts, at its bottom end, the other active region in the semiconductor substrate 101 different from the active region that the bit line contact BC contacts. The second contact part 121 (including Co or CoSi₂ for example), the third contact part 122 (including Ti or TiN for example), and the fourth contact part 123 (including W for example) are formed on the first contact part 120 in that order in the remaining cell contact hole 140 to form the bit line contact CC, which is sandwiched between the side wall structures 131 of the neighboring bit lines BL. Any conventional techniques, such as deposition and polishing, may be used to form the bit line contact CC in the opening 140. Later developed techniques may also be applicable as appropriate.

Following the above process, as shown in FIGS. 1A and 1B, the redistribution layers RDL are formed on the respective cell contacts CC and bit lines BL, and the memory cell capacitors MCC are formed on the respective redistribution layers RDL. The formation of the redistribution layers RDL and the memory cell capacitors MCC as well as other layers may be carried out using conventional techniques, such as deposition, etching, and polishing. Later developed techniques may also be applicable as appropriate. Accordingly, as described above, the present embodiments can effectively prevent or mitigate short circuits between neighboring conductive elements, such as the conductive materials (e.g., poly-Si) of the neighboring bit line contact BC and the cell contact CC. As a result, device production yield can be increased, and overall device cost can be reduced.

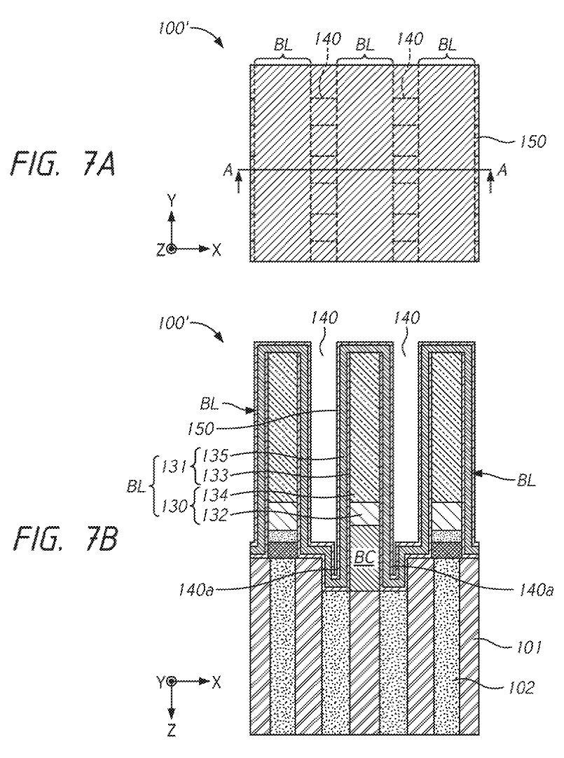

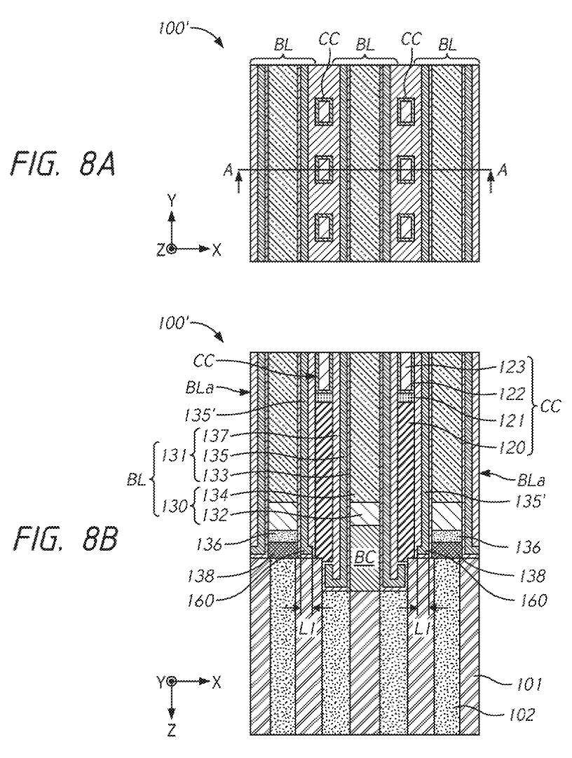

FIGS. 7A-7B - 8A-8B depict example processes of forming at least part of a memory device 100’ in a plan view and a cross-sectional view according to some embodiments of the disclosure. FIGS. 7A and 8A each depicts the process in the plan view. Each of the cross-sectional views in FIGS. 7B and 8B corresponds to line A-A in each of FIGS. 7A and 8A. The size, position, and other aspects of the cross-sectional view may not necessarily match those of the plan view in the drawing. The example process of FIGS. 7A-7B may be performed prior to the etching process of the middle insulating layer 135 shown in FIGS. 3A-3B. In order to protect the middle insulating layer 135 from the etching (especially the wet etching), a thin insulating layer 150 may first be formed on the exposed surfaces of the middle insulating layer 135. The insulating layer 150 may include the same insulating material, such as a nitride (e.g., SiN), as that of the outer insulating layer 137. The insulating layer 150 may serve as a buffer or a protector of the middle insulating layer 135 to prevent a damage to the middle insulating layer 135 (e.g., deterioration of characteristics of the insulating material, such as the low-k material). This buffer/protector insulating layer 150 may become a part of the outer insulating layer 137.

Following the formation of the insulating layer 150, similar processes to those shown in FIGS. 4A-4B - 6A-6B may be applied. The resultant structure of the bit line BL as shown in FIGS. 8A-8B is substantially the same as the bit line BL of FIGS. 6A-6B, except that a neighboring bit line BLa which is illustrated as not including the bit line contact BC has a different bottom portion 160 of the middle insulating layer 135’ from that of the middle insulating layer 135 of the bit line BL. The bottom portion 160 of the middle insulting layer 135’of the bit line BLa has a L-shape. The bit line BLa includes another insulating part 136 and another conductive part 138 under the conductive part 132 in place of the bit line contact BC. The L-shape bottom portion 160 of the middle insulating layer 135’ may further effectively prevent a short circuit between the conductive part 138 of the bit line BLa and the conductive contact part 120 of the cell contact CC on the opposite side from the bit line contact BC.

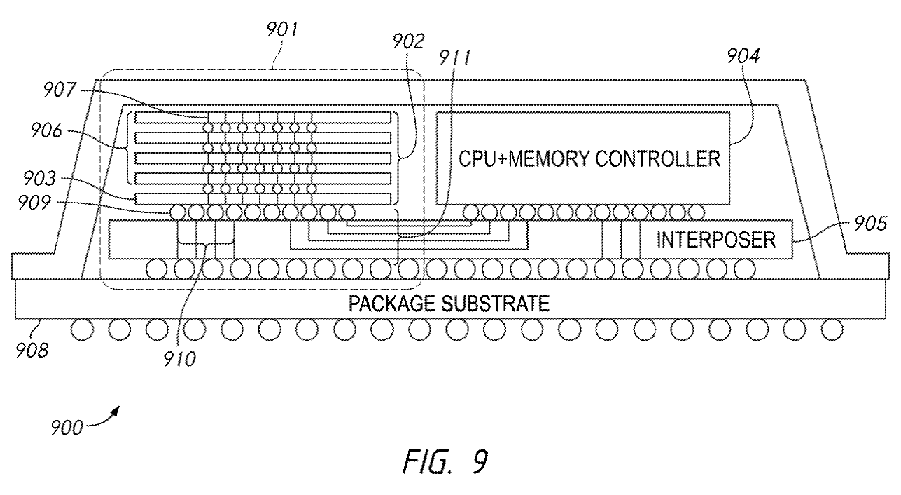

FIG. 9 depicts a schematic configuration of an example semiconductor system 900 according to some embodiments of the disclosure. The semiconductor system 900 includes a semiconductor memory device 901 in an embodiment of the disclosure. In some embodiments of the disclosure, the semiconductor memory device 901 may include the memory device 100 of FIGS. 1A-1B - 6A-6B or the memory device 100’ of FIGS. 7A-7B - 8A-8B. The semiconductor system 900 may also include a central processing unit (CPU) and memory controller 904, which may be a controller chip, on an interposer 905 on a package substrate 908. The interposer 905 may include one or more power lines 910 which may supply power supply voltage from the package substrate 908. The interposer 905 may include a plurality of channels 911 that may interconnect the CPU and memory controller 904 and the semiconductor memory device 901. The semiconductor memory device 901 may be a DRAM. The memory controller 904 may provide a clock signal, a command signal, and may further transmit and receive data signals. The plurality of channels 911 may transmit the data signals between the memory controller and the memory device 901.

The semiconductor memory device 901 may include a plurality of dies (or chips) 902 including at least one interface (IF) die (or chip) 903 and a plurality of memory core dies (or chips) 906 stacked with each other. A number of the memory core dies 906 may not be limited to four as in the illustrated example, and may be more or fewer as appropriate. Each of the memory core dies 906 may include a plurality of memory cells and circuitries accessing the memory cells. For example, the memory cells may be DRAM cells. The memory cells may be arranged in array. The semiconductor memory device 901 may include conductive vias 907 which couple the IF die 903 and the memory core dies 906 by penetrating the IF die 903 and the memory core dies 906. The IF die 903 may be coupled to the interposer 905 via interconnects 909. For example, the interconnects 909 may be microbumps having bump pitches of less than about or less than one hundred micrometers and exposed on an outside of the IF die 903. A portion of each of the interconnects 909 may be coupled to the one or more power lines 910. Another portion of each of the interconnects 909 may be coupled to one or more of the channels 911.

In the above descriptions, DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments.

Thus, it is intended that the scope of the disclosure should not be limited by the particular embodiments described above.

What is claimed is:

1. An apparatus, comprising:
a bit line including a side wall structure, the side wall structure including an inner insulating layer, a middle insulating layer, and an outer insulating layer; and
a bit line contact configured to couple the bit line to an active region formed in a semiconductor substrate, wherein
the outer insulating layer of the side wall structure includes:
a first portion extending along the bit line and the bit line contact; and
a second portion further extending downwardly, the second portion is integral with the first portion, and
the first and second portions of the outer insulating layer and the inner and middle insulating layers are configured to cover side surfaces of the bit line and the bit line contact.

2. The apparatus according to claim 1, wherein the bit line contact extends partway into the semiconductor substrate and is coupled to the active region, and the second portion of the outer insulating layer extends below a top surface of the semiconductor substrate.

3. The apparatus according to claim 2, wherein the middle insulating layer includes a bent lower portion below the top surface of the semiconductor substrate to receive the second portion of the outer insulating layer.

4. The apparatus according to claim 3, wherein the second portion of the outer insulating layer is surrounded by the bent lower portion of the middle insulating layer.

5. The apparatus according to claim 1, wherein the inner insulating layer is on the side surfaces of the bit line and the bit line contact, the middle insulating layer is on the inner insulating layer, and the outer insulating layer is on the middle insulating layer.

6. The apparatus according to claim 1, further comprising a cell contact configured to couple a memory cell capacitor to another active region formed in the semiconductor substrate, wherein the side wall structure is configured to prevent a short circuit between the bit line contact and the cell contact.

7. The apparatus according to claim 6, wherein the second portion of the outer insulating layer extends below a top surface of the semiconductor substrate and prevents the short circuit between the bit line contact and the cell contact below the top surface of the semiconductor substrate.

8. The apparatus according to claim 6, wherein both the bit line contact and the cell contact include polysilicon.

9. The apparatus according to claim 1, wherein the inner insulating layer includes a first insulating material, the middle insulating layer includes a second insulating material, and the outer insulating layer includes a third insulating material, and the second insulting material is different from the first and third insulating materials.

10. The apparatus according to claim 9, wherein the second insulating material includes silicon oxycarbide (SiOC) or silicon oxycarbonitride (SiOCN).

11. An apparatus, comprising:
a bit line including a conductive part;
a bit line contact provided under the conductive part of the bit line and extending partway into a semiconductor substrate, the bit line contact configured to couple the bit line to an active region formed in the semiconductor substrate; and
a side wall structure on side surfaces of the bit line and the bit line contact and extending partway into the semiconductor substrate along the bit line contact, wherein
the side wall structure includes a first insulating layer on the side surfaces of the bit line and the bit line contact, a second insulating layer on the first insulating layer, and a third insulating layer on the second insulating layer, and
the third insulating layer includes a first vertical portion and a second vertical portion integral with the first vertical portion, the second vertical portion protrudes downwardly below a top surface of the semiconductor substrate and is configured to prevent the bit line contact from coupling with a neighboring conductive element.

12. The apparatus according to claim 11, wherein the neighboring conductive element includes a cell contact for a memory cell capacitor, the cell contact coupled to another active region formed in the semiconductor substrate.

13. The apparatus according to claim 12, wherein the bit line and the cell contact include polysilicon.

14. The apparatus according to claim 11, wherein the second insulating layer includes an end portion bent outwardly and upwardly and receives the second vertical portion of the third insulating layer.

15. The apparatus according to claim 14, wherein the second vertical portion of the third insulating layer is surrounded by the bent end portion of the second insulating layer below the top surface of the semiconductor substrate.

16. The apparatus according to claim 14, wherein the third insulating layer includes an insulating material different from an insulating material of the second insulating layer.

17. An apparatus, comprising a multi-layer side wall structure configured to cover side surfaces of a bit line and a bit line contact, the bit line contact extending partway into a semiconductor substrate and the multi-layer side wall structure extending along the bit line contact, wherein
the multi-layer side wall structure includes inner and outer insulating layers and a middle insulating layer between the inner and outer insulating layers, the middle insulating layer including an insulating material different from insulating materials of the inner and outer insulting layers, and
the outer insulating layer includes a downwardly extended portion partway into the semiconductor substrate, and the middle insulating layer includes a lower end portion surrounding the downwardly extended portion of the outer insulating layer.

18. The apparatus according to claim 17, wherein the downwardly extended portion of the outer insulating layer and the lower end portion of the middle insulating layer are located below a top surface of the semiconductor substrate.

19. The apparatus according to claim 18, wherein the downwardly extended portion of the outer insulating layer is configured to prevent a short circuit of the bit line with a neighboring memory cell contact.

20. The apparatus according to claim 19, wherein the downwardly extended portion is integrally formed with an upper vertical portion of the outer insulating layer.
